(19) United States
(12) Patent Application Publication
(10) Pub. No.: US 2006/0118778 A1
(43) Pub. Date: Jun. 8, 2006

(54) Organic electronic component with high-resolution structuring and method for the production thereof

(76) Inventors: Wolfgang Clemens, Puschendorf (DE); Walter Fix, Nurnberg (DE); Alessandro Manuelli, Spinetta M.go (IT); Andreas Ullmann, Zirndorf (DE)

Correspondence Address: CARELLA, BYRNE, BAIN, GILFILLAN, CECCHI,;STEWART & OLSTEIN, 5 BECKER FARM ROAD, ROSELAND, NJ, 07068, US

(21) Appl. No.: 10/533,756

(22) PCT Filed: Nov. 5, 2003
(86) PCT No.: PCT/DE03/03667

§ 371 Date: Jan. 13, 2006

(30) Foreign Application Priority Data
Nov. 5, 2002 (DE) 102 51 475.5

(51) Int. Cl. H01L 29/08

(52) U.S. Cl. 257/40

(57) ABSTRACT

The invention concerns an organic electronic component with high-resolution structuring, in particular an organic field effect transistor (OFET) with a small source-drain spacing, and a process for the production thereof. The organic electronic component has recesses in which the conductor tracks/electrodes are arranged and which are burnt in by means of laser in the production procedure.

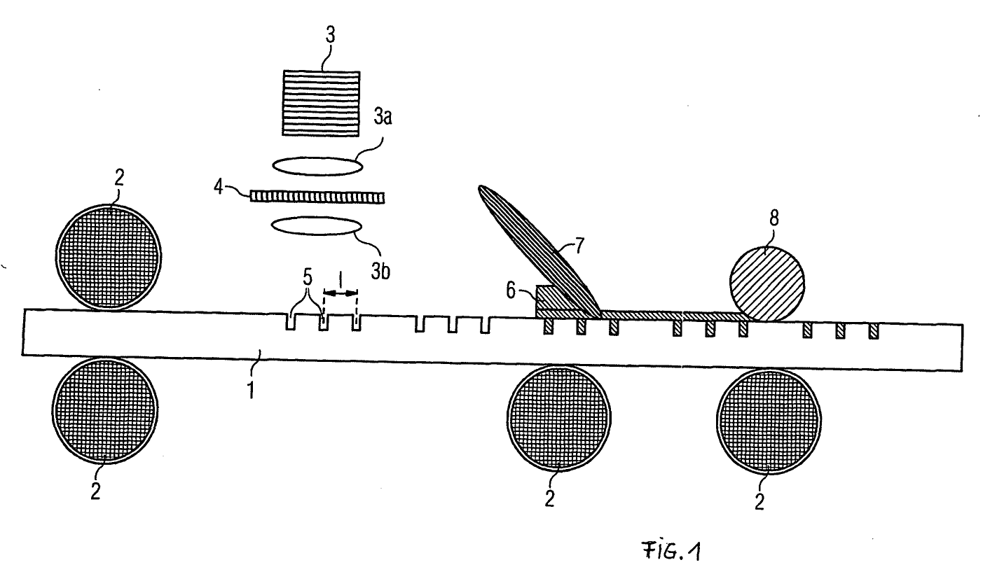

The invention concerns an organic electronic component with high-resolution structuring, in particular an organic field effect transistor (OFET) with a small source-drain spacing, and a process for the production thereof.

Organic electronic components are known, in particular OFETs with high-resolution structuring and a small source-drain spacing ‘I’; but they are produced using expensive process steps which entail high cost levels. Those process steps are uneconomical and usually include photolithography, wherein recesses are produced in a lower layer or in the substrate by photolithographic means so that a conductor track with the required capacitance can be formed. Those recesses are trough-shaped and do not involve sharp contours. The bottom of the recesses remains unchanged.

A conductor track and/or an electrode needs a certain mass in order to have a low resistance, which is best disposed in a 1-2 μm recess. Hitherto however there is no process which, in a quick and inexpensive production procedure, produces the conductor tracks/electrodes of an OFET in that way.

The known processes for producing organic electronic components, which are quick and suitable for mass production, make use of the technology of applying the conductor track to the lower layer, generally therefore to the substrate, in which case the problem which arises is that those ‘superposed’ conductor tracks are either so thick that they cause defect locations in the subsequent insulating layer or layers, or they are so wide that a large part of the overall surface area of the integrated circuit is used for same.

Admittedly, DE 10061297.0 discloses a high-resolution printing process which can be used on a large technological scale and in which the conductor tracks are recessed, but it suffers from the disadvantage that the recesses which are produced by impressing thereon with an embossing stamp do not have steep wall surfaces and sharply defined edges but are more trough-shaped and do not have sharp contours. As a consequence of those gentle transitions, the material introduced into the recess does not accurately fill only the recess, but it smears and smudges around the recess and thus leads to leakage currents. The smeared material also cannot be subsequently wiped off, without wiping a large part of the material out of the recess again.

The object of the invention is to provide an organic electronic component which can be produced on a large technological scale and favourably, in particular an OFET with a high-resolution structure and a small source-drain spacing.

The way in which that object is attained and the subject-matter of the invention is an organic electronic component with a spacing I between two conductor tracks, electrodes and/or between a conductor track and an electrode of less than 10 μm, which has a substantially flat surface, that is to say the conductor track or tracks and/or the electrode or electrodes are raised less than 300 nm above the surface of a lower layer or the substrate. The subject-matter of the invention is also an organic electronic component with a spacing I between two conductor tracks, electrodes and/or between a conductor track and an electrode of less than 10 μm, wherein at least one conductor track and/or electrode is arranged in a recess of a lower layer, wherein the recess was produced by means of a layer, that is to say it has steep walls, sharp contours and a relatively rough bottom surface.

Finally the subject-matter of the invention is a process for the production of an organic electronic component in which to produce a conductor track and/or an electrode at least one recess is burnt into a lower layer or the substrate by means of laser and mask, wherein said recess has steep walls, sharp contours and a rough surface at the bottom, and in a subsequent process step is filled with conductive, predominantly organic material.

In accordance with an embodiment of the process, in a process step following the step of filling the recesses with said conductive organic material, excess conductive organic material is wiped away without in that case conductive material being removed from the recess to a noticeable extent again.

The recesses can be filled using various procedures: the material can be sprayed, scraped in by a blade, injected, applied by coating, applied by printing or introduced into the recesses in any other manner according to the invention.

In accordance with an embodiment of the process the recesses are burnt into the lower layer and/or the substrate with a pulsed layer, for example with pulse lengths of some 10 ns. In that case a few pulses can already suffice to produce recesses in the region of between 0.5 and 3 82 m.

The recesses produced by laser structuring are distinguished in that the walls are very steep and in the extreme case directly perpendicular. In addition the vaporisation effect produces a very rough surface at the bottom of the recesses, which has the consequence that the organic conductor introduced has very good adhesion there and is not sucked out of and/or removed from the recesses to any extent worth mentioning, by virtue of the operation of removing the excess conductive material between the recesses. In that way, the recesses which are burnt in with laser are also clearly distinguished from the recesses which are produced for example by embossing, where the excess organic material which is distributed around the recess cannot be wiped away without involving serious losses.

The invention is described in greater detail hereinafter with reference to a FIGURE which shows by way of example a diagrammatic view of a process sequence for the production of a conductor track and/or an electrode.

The substrate 1 is drawn through between a plurality of rollers for example in a roll-to-roll process. Shown from left to right are firstly the pressing and/or guide rollers 2 which promote a uniform travel movement of the strip. In the first working operation illustrated, recesses 5 are then produced in the substrate with a laser 3, for example an excimer laser, through a mask 4. The excimer laser 3 is possibly provided with optical lens systems 3a, 3b so that the recesses 5 are not necessarily imaged in the same size as predetermined by the mask 4. As the laser pulse lasts for example only a few 10 ns, the strip 1 has advanced only insignificantly in time. As described above, the recesses 5 produced in that way have sharp edges, steep walls and a rough bottom surface to which the organic conductors particularly firmly adhere. Then, using a doctor blade 7, organic electrically conductive material 6 such as for example PANI (polyaniline) or PEDOT in solution or in the form of a paste is scraped into the recesses. Any conductive material 6 which may be present between the recesses is then removed with an absorbent roller 8. The roller 8 rotates for example more slowly than the other rollers so that the material is effectively wiped off. The spacing between two recesses 5 is identified by the double-headed arrow and is denoted by I.

The term ‘organic polymer’ or ‘functional material’ or ‘(functional) polymer’ here embraces all kinds of organic, metallorganic and/or organic-inorganic plastic materials (hybrids), in particular those which are identified in English for example by ‘plastics’. This involves all kinds of substances with the exception of the semiconductors which form the conventional diodes (germanium, silicon) and the typical metallic conductors. Restriction in a dogmatic sense to organic material as carbon-bearing material is accordingly not intended, but rather the broad use of for example silicones is also envisaged. In addition the term is not to be subjected to any restriction in regard to the molecule size, in particular to polymeric and/or oligomeric materials, but the use of small molecules is certainly also possible. The word component ‘polymer’ in the expression functional polymer is historically governed and in that respect does not make any statement about the presence of an actually polymeric bond.

The invention for the first time provides a process with which an organic electronic component such as an OFET with a high switching speed and a high level of reliability can be economically produced. It has been found that recesses which are burnt in with a laser hold the filling with conductive organic material differently from the conventional recesses and that therefore organic conductor tracks can be produced more quickly and better with this method than with other methods.

1. An organic electronic component including a lower layer having a top surface with a spacing I between two adjacent conductor tracks, two adjacent electrodes and/or between a conductor track and an electrode of less than 10 μm in the lower layer, wherein at least one conductor track and/or electrode is arranged in a recess of the lower layer, wherein the recess is produced by a laser, the recess having relatively steep side walls generally perpendicular to the top surface and a bottom surface, the recess exhibiting relatively sharp contours at the junction of the side walls with the bottom recess surface and with the lower layer top surface and a relatively rough bottom surface as compared to the top surface of the lower layer.

2. A process for the production of an organic electronic component including a substrate or lower layer having a top surface, the process for producing a conductor track and/or an electrode in the substrate or lower layer by burning at least one recess into the lower layer or into the substrate by emitting a laser beam through a mask, wherein said recess has a bottom surface and relatively steep walls relative to the top surface, the recess exhibiting relatively sharp contours between the side walls and bottom surface and between the side walls and the top surface and a rough surface at the bottom surface as compared to the top surface, and then filling the recess in a subsequent process step with conductive, predominantly organic material.

3. A process as set for the in claim 2 wherein the conductive material is scraped into the recess.

4. A process as set forth in one of claims 2 and 3 wherein excess conductive organic material is wiped away in a process step following the step of filling the recess with said material.

5. A process as set forth in one of claims 2 through 3 wherein the laser is pulsed.

6. A process as set forth in one of claims 2 through 3 which is performed in a continuous roll-to-roll procedure.

7. A process as set forth in claim 6 wherein the roll-to-roll procedure including pressing or guiding the substrate or lower layer with pressing or guide rollers and wiping off the excess organic material from the top surface with a wiping roller, the wiping roller rotating more slowly than the pressing or guide rollers.

8. The process as set forth in one of claims 2 and 3 wherein the laser is an excimer laser.
